(19) United States
(12) Patent Application Publication
(10) Pub. No.: US 2023/0369168 A1
(43) Pub. Date: Nov. 16, 2023

(54) PACKAGE HAVING METAL SKELETON FRAME USING EMBEDDED GROUND PLANE

(71) Applicant: NXP B.V., Eindhoven (NL)

(72) Inventors: Kuan-Hsiang Mao, Kaohsiung (TW); Chin Teck Siong, Selangor (MY); Wen Hung Huang, Kaohsiung (TW)

(21) Appl. No.: 17/740,554

(22) Filed: May 10, 2022

(51) Int. Cl. H01L 23/48; H01L 23/00; H01L 21/56

(52) U.S. Cl. CPC H01L 23/481; H01L 24/19; H01L 21/565; H01L 24/20; H01L 2224/214; H01L 2224/211; H01L 2224/2105; H01L 2224/2101; H01L 2924/182; H01L 2924/183; H01L 2924/3511; H01L 2924/3025

(57) ABSTRACT

An integrated circuit (IC) package includes one or more microelectronic devices disposed between a first side and an opposing second side of the IC package and further includes a metal frame structure comprising a metal layer disposed at the second side, an embedded ground plane (EGP) structure encircling the one or more microelectronic devices, and a set of stacked conductive structures extending from the EGP structure to the first side through a set of one or more redistribution layers at the first side. The IC package further can include an array of package contacts disposed at the first side and an encapsulant layer encapsulating the one or more microelectronic devices in a volume defined by an inner sidewall of the EGP structure.

### BACKGROUND

Redistributed chip packages (RCPs) and other fan-out-type substrate-less integrated circuit (IC) packages employ one or more integrated circuit (IC) die, surface mount IC devices (SMDs) or other microelectronic devices embedded in molding (or encapsulant) with one or more redistribution layers (RDLs) at a front side of the package to provide electrical routes between the pads of the microelectronic device(s) and the contact array of the package. In some instances, the package further may employ an embedded ground plane (EGP) embedded in the molding and which substantially or fully encircles the IC die. The EGP can provide one or both of electromagnetic interference (EMI) shielding or a package-level distribution structure for ground or another reference voltage. Because such packages are substrate-less, they can provide a low-cost, high-performance alternative to traditional substrate packaging that utilizes wire bonds or flip-chip techniques. However, conventional approaches to substrate-less packages are subject to mechanical warpage and other stresses during handling and placement due to the lack of structural integrity that the absent substrate otherwise would provide.

### SUMMARY OF EMBODIMENTS

In accordance with one aspect, an IC package includes one or more microelectronic devices disposed between a first side and an opposing second side of the IC package. The IC package further includes a metal frame structure comprising a metal layer disposed at the second side, an embedded ground plane (EGP) structure encircling the one or more microelectronic devices, and a set of stacked conductive structures extending from the EGP structure to the first side through a set of one or more redistribution layers at the first side.

The IC package further may include one or more of the following features, individually or in combination: wherein the stacked conductive structures of the set are aligned with a surface of the EGP structure facing the first side; the set of stacked conductive structures comprises a stacked conductive structure at each corner of the EGP structure; wherein the stacked conductive structures of the set each comprises a stack of two or more conductive structures, each conductive structure of the stack extending through a corresponding redistribution layer of the set of one or more redistribution layers; wherein the conductive structure comprises a conductive via; an array of package contacts disposed at the first side; wherein the array comprises a package contact overlying, and in electrical contact with, a stacked conductive structure of the set of stacked conductive structures; wherein the package contact overlying the stacked conductive structure is a mechanical package contact for providing mechanical bonding with another component of an electrical device; wherein the metal frame structure is composed of at least one of copper or a copper alloy; or wherein the one or more microelectronic devices comprise at least one of one or more surface mount IC devices or one or more IC die.

In accordance with another aspect, an IC package includes an array of package contacts disposed at a first side of the IC package, a metal layer disposed at an opposing second side of the IC package, one or more microelectronic devices disposed in the IC package between the first and second sides, an EGP structure embedded in the IC package between the first and second sides and encircling the one or more microelectronic devices, wherein the EGP structure is mechanically and electrically connected to the metal layer, a set of redistribution layers disposed between the one or more microelectronic devices and the array of package contacts and comprising conductive structures providing conductive pathways between contacts of the one or more microelectronic devices and corresponding package contacts of the array of package contacts, and a set of stacked conductive structures disposed at the first side of the IC package and aligned with a surface of the EGP structure facing the first side of the IC package, each stacked conductive structure of the set extending from the first side of the IC package to the surface of the EGP structure through the set of one or more redistribution layers and being mechanically and electrically connected to the surface of the EGP structure.

The IC package further may include one or more of the following features, individually or in combination: package encapsulant extending between the metal layer and the set of redistribution layers and encapsulating the one or more microelectronic devices in a volume defined by the EGP structure; or wherein each stacked conductive structure of the set comprises a stack of conductive vias, each conductive via extending through a corresponding redistribution layer of the set of redistribution layers.

In accordance with yet another aspect, a method of fabrication of an IC package includes: forming a workpiece comprising an EGP structure and the one or more microelectronic devices disposed in a volume defined by the EGP structure; encapsulating the workpiece in an encapsulant; fabricating a set of redistribution layers at a first side of the workpiece; fabricating a set of stacked conductive structures that extend from the first side of the workpiece to a first surface of the EGP structure through the set of redistribution layers, each stacked conductive structure being mechanically and electrically connected to the EGP structure at the first surface; removing encapsulant at a second side of the workpiece opposite the first side to expose a second surface of the EGP structure opposite the first surface; and forming a metal layer at the second side of the workpiece, the metal layer mechanically and electrically connected to the second surface of the EGP structure.

The IC package further may include one or more of the following features, individually or in combination: wherein each stacked conductive structure includes a stack of conductive structures, and wherein fabricating the set of stacked conductive structures comprises for each redistribution layer formed at the first side of the workpiece, forming a corresponding conductive structure for each stack of conductive structures, the conductive structure extending through the redistribution layer; wherein forming the corresponding conductive structure comprises forming one of a conductive via that extends through the redistribution layer; forming an array of package contacts at the first side of the workpiece after forming the set of redistribution layers; wherein forming the array of package contacts further comprises forming a package contact overlying, and in electrical contact with, a stacked conductive structure of the set; singulating the workpiece to form the IC package; or wherein the one or more microelectronic devices comprise at least one of one or more surface mount IC devices or one or more IC die.

### BRIEF DESCRIPTION OF THE DRAWINGS

The present disclosure is better understood, and its numerous features and advantages made apparent to those skilled in the art, by referencing the accompanying drawings. The use of the same reference symbols in different drawings indicates similar or identical items.

FIG. 1 is a cross-section view of an IC package utilizing an embedded EGP-based metal skeleton frame in accordance with some embodiments.

FIG. 2 is a plan view of the IC package of FIG. 1 in accordance with some embodiments.

FIG. 3 is a plan view of a portion of the IC package of FIG. 1 having a rivet-mounted package bump in accordance with some embodiments.

FIGS. 4 and 5 together illustrate a method for fabricating an IC package having an embedded EGP-based metal skeleton frame in accordance with some embodiments.

### DETAILED DESCRIPTION

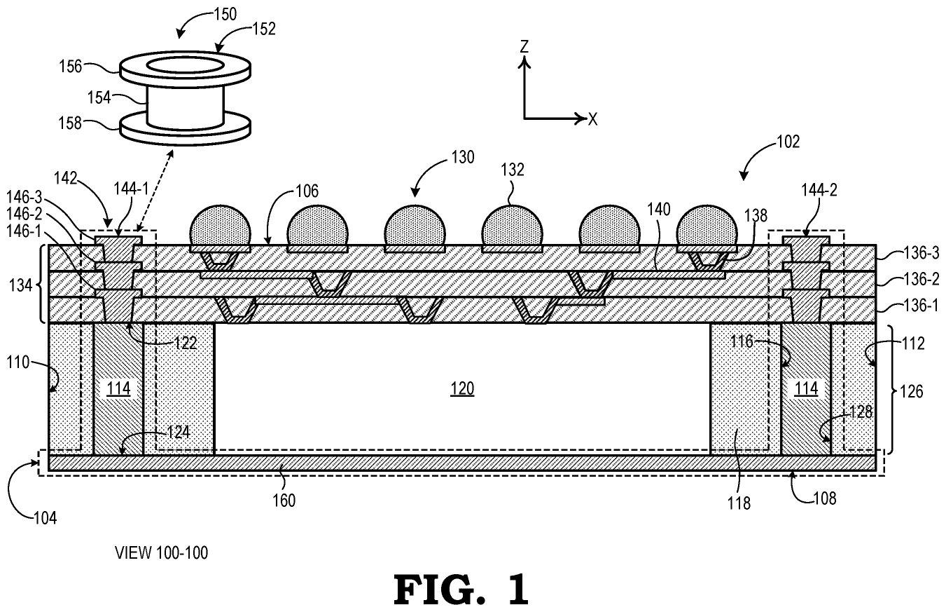

FIGS. 1-5 illustrate embodiments of an integrated circuit (IC) package employing a metal skeleton frame utilizing an embedded ground plane (EGP) structure to provide one or more of improved package rigidity, improved electrical isolation, or improved heat dissipation. As with conventional substrate-less/fan-out IC packages having an EGP structure, embodiments of the IC package described herein implement an EGP structure that encircles one or more microelectronic devices, such as surface mount IC devices (SMDs) or IC die. However, in at least one embodiment, the IC package described herein further utilizes the EGP structure as the foundation of a metal skeleton frame for the package. The metal skeleton frame further includes a set of stacked conductive structures that extend through the redistribution layers (RDLs) formed at a first, or front, side of the IC package to a first surface of the EGP structure that faces the first side. Each stacked conductive structure has a mechanical and electrical connection with the EGP structure. The stacked conductive structure, in some embodiments, is formed of a stack of conductive structures, one for each RDL of the IC package, such that each conductive structure of the stack extends through a corresponding RDL and is either in electrical and mechanical contact with either the next conductive structure or in electrical and mechanical contact with the first surface of the EGP structure, depending on the position of the conductive structure within the stack, and thus acting as, in effect, a conductive rivet that structurally reinforces the attachment of the RDL to the underlying components of the package. At the second, or back, side of the IC package, a metal layer is formed to be in electrical and mechanical contact with a second surface of the EGP structure that is opposite the first surface.

In this approach, the mechanical bond between the EGP structure, the metal layer, and the set of stacked conductive structures forms, in effect, a continuous metal skeleton frame for the IC package that extends between the two opposing sides of the IC package and which spans a substantial portion of the lateral extent of the IC package. Thus, this metal skeleton frame can provide enhanced mechanical rigidity to the IC package, and thereby make the IC package less susceptible to warpage or breakage during handling and placement. Further, the metal layer and set of stacked conductive structures provide paths for routing thermal energy away from the EGP structure towards either or both of the first and second sides of the IC package and thus provide for improved heat dissipation for the one or more microelectronic devices encircled by the EGP structure. Moreover, as this metal skeleton frame provides metal structures at the second side and at or near the sidewalls of the IC package, the metal skeleton can provide improved electrical isolation for one or more microelectronic devices embedded therein, as well as for the electrical redistribution paths formed in the set of RDLs of the IC package.

Note that in the following, certain positional terms, such as top, bottom, front, back, side, and the like, are used in a relative sense to describe the positional relationship of various components. These terms are used with reference to the relative position of components either as shown in the corresponding figure or as used by convention in the art and are not intended to be interpreted in an absolute sense with reference to a field of gravity. Thus, for example, a surface shown in the drawing and referred to as a top surface of a component would still be properly understood as being the top surface of the component, even if, in implementation, the component was placed in an inverted position with respect to the position shown in the corresponding figure and described in this disclosure. Moreover, it will be appreciated that for simplicity and clarity of illustration, components shown in the figures have not necessarily been drawn to scale. For example, the dimensions of some of the components may be exaggerated relative to other components. It further will be appreciated that although certain actions are described in a particular order for ease of description, certain actions may be performed in a different order than that described or omitted entirely, unless described otherwise herein.

It also should be noted that the term “metal” as used herein shall be understood to refer to an elemental metal (e.g., copper (Cu) or nickel (Ni)), a metal alloy (e.g., a copper-nickel alloy), a combination of metals, a combination of metal alloys, or a combination of one or more metals and one or more metal alloys (e.g., a copper layer with a copper-nickel-palladium plating).

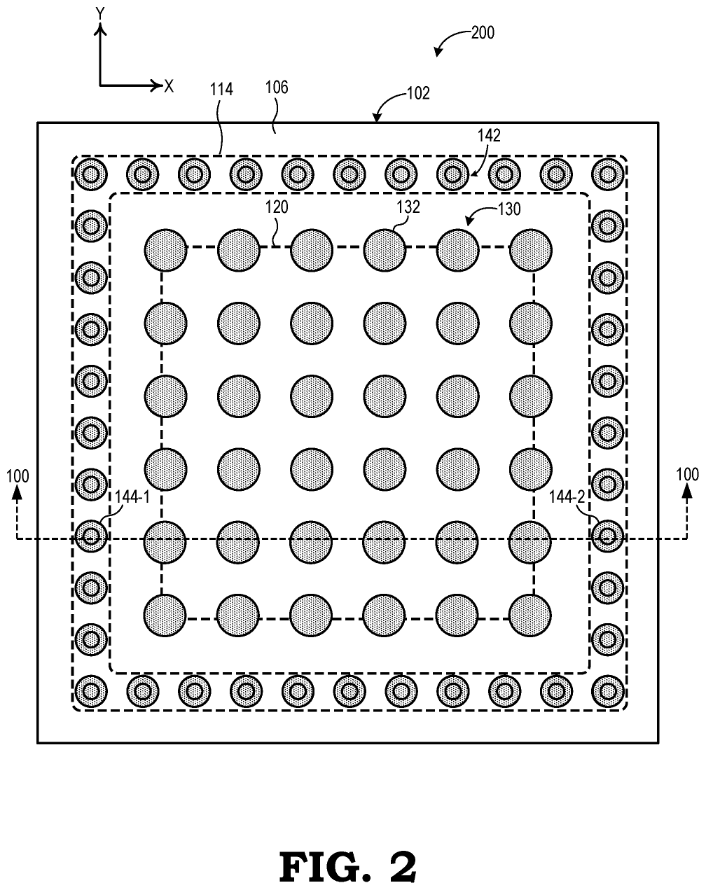

FIGS. 1 and 2 illustrate a cross-section view 100 and plan view 200, respectively, of an integrated circuit (IC) package 102 having a metal skeleton frame 104 in accordance with at least one embodiment of the present disclosure. The IC package 102 has a first side 106 and an opposing back side 108 (referred to herein as “front side 106” and “back side 108” for ease of reference), as well as opposing sidewalls 110 and 112. Embedded in the IC package 102 between the front side 106 and the back side 108 is an embedded ground plane (EGP) structure 114 composed of one or more metals, such as copper or a copper alloy. EGP structures, such as the EGP structure 114, are employed in fan-out IC packages as three-dimensional (3D) conductive structures that form a conductive “wall” that substantially or fully encircle the microelectronic device(s) contained therein to provide electrical isolation and thermal dissipation for the microelectronic devices, and in some instances to provide for the distribution of ground or other reference voltage. The EGP structure 114 can employ any of a variety of encircling shapes, such as the rectangular perimeter shape shown by plan view 200 of FIG. 2, with either sharp or rounded corners. Other example encircling shapes can include, for example, circles, ovoid shapes, triangular shapes, pentagons, hexagons, and other regular or irregularly-shaped polygons. The inner sidewall 116 of the EGP structure 114 defines an aperture 118, or volume, in which one or more microelectronic devices 120 are positioned. Although the depicted IC package 102 includes only a single microelectronic device 120, it will be appreciated that more than one microelectronic device 120 may be positioned side-by-side in the aperture 118, depending on implementation. The microelectronic device(s) 120 can include one or more SMDs, one or more IC die, or a combination thereof. In the depicted embodiment, the microelectronic device 120 has a dimension along the illustrated Z-axis that is substantially equal to a dimension along the Z-axis between opposing surfaces 122, 124 of the EGP structure 114. However, in other embodiments, the microelectronic device 120 may be “shorter” than the EGP structure 114 along this reference axis. The IC package 102 further includes an encapsulant layer 126 composed of any of a variety of suitable encapsulants or molding compounds that encapsulates the one or more microelectronic devices 120 in the aperture 118, and in the illustrated embodiment, extends laterally along the X-axis beyond an outer sidewall 128 of the EGP structure 114.

The front side 106 serves as the mounting surface for mounting the IC package 102 to a substrate or another component of an electronic device, and thus includes an array 130 of package contacts 132 disposed at the front side 106. The package contacts 132 can include any of a variety of types of package contacts, such as, for example, ball grid array (BGA) bumps, metal pillars, metal posts, and the like. Although a regular 6×6 array 130 is illustrated, it will be appreciated that the array 130 may comprise any number of package contacts 132, and may be an irregular array, an array of package contacts 132 primarily at the perimeter or an array of package contacts that substantially span the front side 106, and the like.

In at least one embodiment, the IC package 102 is a substrate-less IC package and thus utilizes a set 134 of redistribution layers (RDLs) 136 disposed between the EGP structure 114/microelectronic device(s) 120 and the front side 106 and which provide fan-out contact routing between contacts of the one or more microelectronic devices 120 and the array 130 of package contacts 132 at the front side 106 of the IC package 102. In the illustrated example, the set 134 includes three RDLs 136, denoted RDLs 136-1, 136-2, and 136-3. However, any number of RDLs 136 may be employed in the set 134 depending on implementation. Each RDL 136 includes a passivation layer or other dielectric layer in which one or more vias (e.g., via 138), traces (e.g., trace 140), or other conductive structures are formed to provide corresponding portions of conductive paths between contacts of the one or more microelectronic devices 120 and the package contacts 132.

In at least one embodiment the IC package 102 further includes a set 142 of stacked conductive structures 144 extending from the front side 106 (e.g., the top surface of the top-most RDL 136-3 in the illustrated example) to the front-side-facing surface 122 of the EGP structure 114. As shown by plan view 200, the stacked conductive structures 144 are aligned with the EGP structure 114 in the Z-direction. The set 142 can include any number of conductive structures 144, such as the forty stacked conductive structures 144 shown in FIG. 2. In other implementations, the set 142 could be composed of a smaller or larger number of stacked conductive structures 144 per side of the IC package 102, such as, for example, four stacked conductive structures 144, one at each corner of the rectangular perimeter formed by the illustrated EGP structure 114. In at least one embodiment, each stacked conductive structure 144 comprises a stack of conductive structures 146 equal in number to the number of RDLs 136 in the set 134, with each conductive structure 146 extending through a corresponding RDL 136 and being mechanically and electrically connected to the conductive structure 146 “below” it in the stack, or if the conductive structure 146 closest to the surface 122 of the EGP structure 114, mechanically and electrically connected to the surface 122 of the EGP structure 114.

For example, cross-section view 100 depicts two stacked conductive structures 144-1 and 144-2. Stacked conductive structure 144-1 is composed of three conductive structures 146-1, 146-2, and 146-3. The conductive structure 146-1 extends through RDL 136-1 and is electrically and mechanically connected to the surface 122 of the EGP structure 114 at the bottom of the conductive structure 146-1. The conductive structure 146-2 extends through RDL 136-2 and the bottom of the conductive structure 146-2 is electrically and mechanically connected to the top of the conductive structure 146-1. The conductive structure 146-3 extends through RDL 136-3 and the bottom of the conductive structure 146-3 is electrically and mechanically connected to the top of the conductive structure 146-2, while the top of the conductive structure 146-3 is exposed at the front side 106 of the IC package 102. Thus, the three conductive structures 146-1, 146-2, and 146-3 in the stacked configuration together form a rigid structure that helps to mechanically affix the set 134 of RDLs 136 to the EGP structure 114, as well as providing either or both of a thermally conductive path or an electrically conductive path between the EGP structure 114 and the front side 106. The stacked conductive structure 144-2 is likewise configured with three conductive structures 146 at the opposing side of the EGP structure 114 and thus serves to assist in providing structural rigidity and a thermal/electrical conductive path on the other side of the IC package 102.

The conductive structures 146 that stack to form the stacked conductive structure 144 can comprise any of a variety or combination of conductive structures suitable for fabrication in an RDL and which provide sufficient mechanical bonding with the adjacent conductive structure(s) in the stack and/or the EGP structure 114. Such conductive structures can include, for example, conductive vias or other vertical interconnects. For example, isometric view 150 of FIG. 1 depicts components of an example implementation of the conductive structure 146 as a dummy plated vertical interconnect 152. In this example, the dummy plated vertical interconnect 152 is formed as a via 154 (or through hole) that extends through the dielectric layer of the corresponding RDL 136 and connects a top metal pad 156 formed on “top” of the corresponding RDL 136 and a bottom metal pad 158 formed on the “bottom” of the corresponding RDL 136, with the via 154 is plated or filled with one or more conductive materials to mechanically and electrically connect the metal pads 156 and 158. Note that, except for the bottom dummy plated vertical interconnect 152 in the stack, the bottom metal pad 158 is also the top metal pad 158 for the next dummy plated vertical interconnect 152 in the stack. For the bottom dummy plated vertical interconnect 152, the bottom metal pad 158 may be omitted, with the via 154 being placed in direct mechanical and electrical contact with the surface 122 of the EGP structure 114 or the bottom metal pad 158 may be formed on, and in mechanical and electrical contact with, the surface 122 of the EGP structure 114. In some embodiments, the fabrication of a via hole in which the conductive structure 146 is formed via plating or other metallization process utilizes a process that forms the via so that it has an “upper” opening (that is, the opening closer to the top surface 106) that is larger than the “lower” opening (that is, the opening closer to the bottom surface 108). Doing so helps to ensure that the “lower” end of the resulting conductive via or other vertical interconnect is smaller than the “upper” end of the conductive via or other vertical interconnect below it and to which it is placed in mechanical and electrical contact, and thus mitigating the risk of the dimple phenomena that can lead to detachment of one conductive structure 146 from another. As will be appreciated from the description above and below, the vertical interconnect 152 extends through a corresponding RDL and mechanically attaches to the vertical interconnect 152 below it, and thus serves to, in effect, “rivet” the corresponding RDL to the EGP structure 114. As such, the conductive structure 146 is also referred to herein as a “rivet” as a reflection of its riveting effect on providing further structural attachment between the corresponding RDL layer and the EGP structure 114.

The back side 108 of the IC package 102 includes a metal layer 160 that laterally extends in the X-Y plane at least across the EGP structure 114, and in the illustrated example, extends the full lateral extent of the IC package 102 in the X and Y directions. The metal layer 160 is composed of one or more elemental metals (e.g., copper (Cu)), one or more metal alloys (e.g., a copper alloy), or a combination thereof, and may be composed of a single layer or multiple sublayers of the same or different compositions (e.g., a base copper layer that is then plated with nickel (Ni), silver (Ag), and/or palladium (Pd)-based materials for corrosion resistance). The metal layer 160 is in mechanical and electrical contact with the bottom-side-facing surface 124 of the EGP structure 114. In implementations in which the microelectronic device(s) 120 are of equivalent “height” as the EP structure 114 in the Z-direction, the metal layer 160 also is in mechanical contact with the back side surfaces of the microelectronic device(s) 120. In implementations when the microelectronic device(s) 120 are of shorter “height” than the EP structure 114, then a thermal interposer (not shown), such as a thermal pad or thermal paste, can be disposed between the back side surfaces of the microelectronic devices 120 and the facing surface of the metal layer 160 to provide a continuous thermal conduction path between the microelectronic device(s) 120 and the metal layer 160.

As shown by cross-section view 100 of FIG. 1, the stacked conductive structures 144, the EGP structure 114, and the metal layer 160, and the mechanical, thermal, and electrical connections therebetween, together form a continuous metal skeleton frame 104 for the IC package that facilitates one or more of increased structural rigidity, thermal dissipation, or electrical isolation. To illustrate, the EGP structure 114 forms the foundation for a relatively rigid lateral structure in the IC package 102, and the set 142 of stacked conductive structures 144 serve to further “adhere” the set 134 of RDLs 136 to the EGP structure 114, and the resulting rigidity is further bolstered by the metal layer 160 that extends laterally between the sides of the EGP structure 114. Similarly, the metal layer 160 serves to facilitate heat dissipation from the microelectronic device(s) 120, both through thermal radiation into the environment proximate to the external surface of the metal layer 160 (that is, the back side 108) as well as through thermal conduction to the front side 106 via thermal conduction pathways formed through the connection of the metal layer 160 to the EGP structure 114 and through the connections between the EGP structure 114 and the stacked conductive structures 144. Likewise, the metal of the EGP structure 114, the metal layer 160, and the stacked conductive structures 144 provide EMI barriers on five of six sides of the microelectronic device(s) 120 and the conductive paths formed in the RDLs 136.

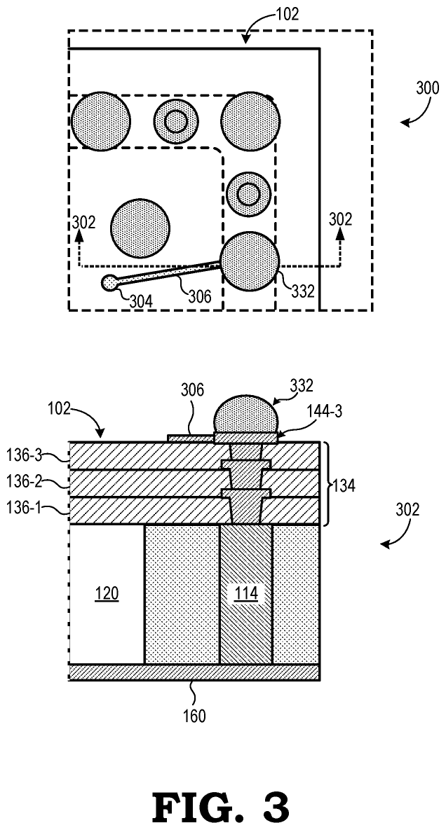

Moreover, the exposure of the stacked conductive structures 144 at the front side 106 can facilitate electrical connection between package contacts formed at the front side 106 and the EGP structure 114 and the metal layer 160, and thus facilitate distribution of ground or another reference voltage (e.g., Vcc). For example, FIG. 3 illustrates a top view 300 and cross-section view 302 of a corner of an implementation of the IC package 102 in which the area of the front side 106 of the IC package overlying the EGP structure 114 is open for redistribution paths connected to package contacts that can be used for ground (or other voltage reference) distribution or for mechanical bonding. In this approach, a package contact can be formed at, or proximate to, a corresponding stacked conductive structure 144.

For example, as depicted by views 300 and 302 a package contact 332 can be formed overlying (and in mechanical and electrical contact with) a stacked conductive structure 144-3 of the set 142. The package contact 332 can use the top conductive structure 146 of the stacked conductive structure 144-3 as the contact pad (or “under ball mount” or UBM) for a corresponding solder ball, pin, column, etc., or a separate contact pad may be formed at least partially overlying the top conductive structure 146. In this form, the package contact 332 provides a mechanical attachment between the IC package 102 and the substrate or other electrical device component upon which the IC package 102 is mounted, and more particularly, a direct mechanical connection between the metal skeleton frame 104 of the IC package 102 and the underlying substrate/electrical device component, which provides further structural rigidity. Moreover, an overlying package contact, such as package contact 332, can provide a path for distributing ground or a reference voltage to the EGP structure 114 and the metal layer 160.

Still further, conductive paths formed in the RDLs 136 and linked to a corresponding stacked conductive structure 144 can be used to distribute this ground or other reference voltage to the microelectronic device(s) 120 embedded in the IC package. To illustrate, a conductive path can be formed in the set 134 of RDLs 136, the conductive path including a conductive via 304 and a trace 306 formed in the top RDL 136-3. The via 304 is electrically connected to other conductive structures in the set 134 of RDLs 136 that in turn are connected to a contact of the microelectronic device 120. In turn, the trace 306 connects the via 304 to the stacked conductive structure 144-3 and the package contact 332, and thus connects the conductive path to the metal skeleton frame 104 and the reference voltage supplied thereby.

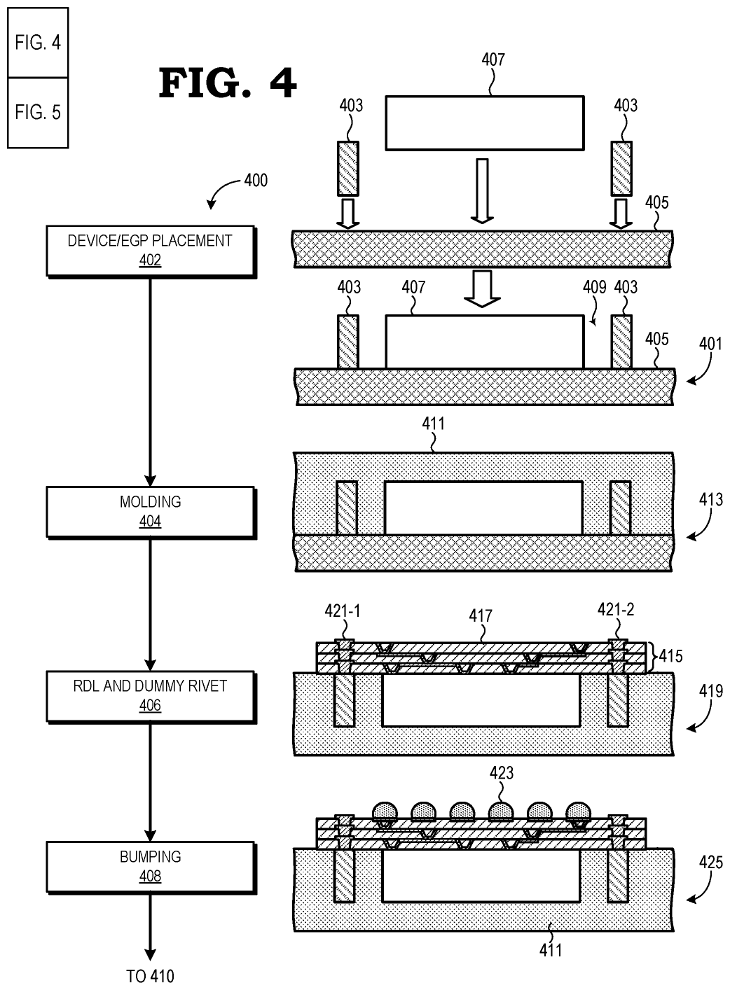

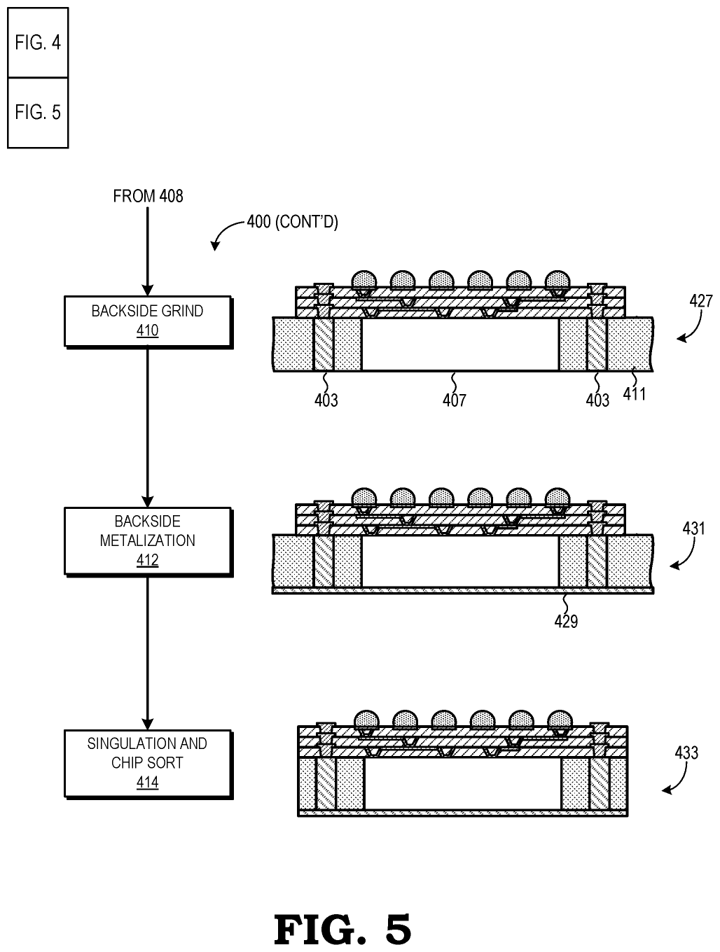

FIGS. 4 and 5 together illustrate a method 400 of fabrication of an IC package implementing a metal skeleton frame based on an embedded EGP structure in accordance with at least one embodiment of the present disclosure. For ease of illustration, the method 400 is described in the example context of fabrication of the IC package 102 of FIGS. 1-3, but is not limited to this example description.

The method 400 initiates at block 402 with the fabrication of an initial workpiece 401 by the placement of an EGP structure 403 (one embodiment of EGP structure 114) on a form carrier 405 (e.g., a panel form carrier or wafer form carrier) and then placing one or more microelectronic devices 407 (one embodiment of microelectronic device 120) into the volume 409 defined by the interior sidewall of the EGP structure 403, such that the bottom side of the microelectronic device 407 is adhered to the facing surface of the form carrier 405. It will be appreciated that the workpiece 401 typically is one workpiece in an M×N array of workpieces (M, N>=1) being concurrently processed as a set, but is illustrated as a separate, single workpiece for ease of illustration and description.

At block 404, a molding process is performed to encapsulate the workpiece 401 in an encapsulant 411 that encapsulates the microelectronic device(s) 407 in the volume 409 to form a modified workpiece 413. In some embodiments, the molding process fully encapsulates the EGP structure 403 such that the encapsulant layer formed by the encapsulant 411 extends laterally beyond the exterior sidewall of the EGP structure 403 and above the top surface of the EGP structure 403.

At block 406, the form carrier 405 is removed and a fan-out/RDL process is performed to form a set 415 of RDLs (e.g., RDLs 136, FIGS. 1 and 2) that include various conductive structures to provide electrically conductive paths from contacts of the microelectronic device(s) 407 to the front side 417 of the resulting modified workpiece 419. Any of a variety of well-known or proprietary techniques may be employed to fabricate the set 415 of RDLs. For example, many such techniques involve a layer-by-layer build-up approach whereby a series of dielectric layers (such as polyimide or benzocyclobutene) is successively spun-on or otherwise deposited on the workpiece 419. After each dielectric layer is formed, the dielectric layer is patterned using, for example, photolithography and is based on via and trace locations intended for that dielectric layer, then a metallization process is performed whereby the metal traces and vias are formed in the patterned dielectric layer using, for example, vapor deposition, sputtering, or other deposition process. The resulting RDL can then be passivated, cured, or otherwise processed and the process then repeats for the next RDL in the stack of RDLs.

Further at block 406, and as part of the fan-out/RDL process, a set of stacked conductive structures, such as the illustrated stacked conductive structures 421-1 and 421-2 (e.g., embodiments of the stacked conductive structures 144-1 and 144-2, FIGS. 1 and 2), are formed in the set 415 of RDLs to extend from the top surface of the set 415 to the facing surface of the EGP structure 403, such that the “bottom” conductive structure of the stacked conductive structure is electrically and mechanically connected to the facing surface of the EGP structure 403, and each successive conductive structure in the stacked conductive structure is mechanically and electrically connected to the conductive structure “below” it in the stack. Typically, each conductive structure of the stacked conductive structure is formed as part of the formation of the corresponding RDL through which it extends. For example, as the “bottom” RDL is formed, the bottom conductive structures for all of the stacked conductive structures of the set 415 are formed in this bottom RDL to extend through the bottom RDL to the EGP structure 403, and then for the next RDL, the next conductive structures in the stacks are formed in the next RDL to extend to the bottom conductive structure, and so forth. The formation of a conductive structure of the stacked conductive structure 421 at a given RDL typically involves the formation of a via hole (which, as noted above, may have a taper from “top” to “bottom”) via etching, excimer laser, and the like, and then the metallization of the via hole via, for example, an electroplating deposit process.

After the formation of the set 415 of RDLs is completed, at block 408 a bumping process is performed to fabricate an array of package contacts 423 (embodiments of the array 130 of package contacts 132) at the top side of the workpiece 419, resulting in a modified workpiece 425. Any of a variety of package contact types may be fabricated, such as BGA balls, copper pillars, wire bond pads, and the like. As described above, but not illustrated in FIG. 4, package contacts may be formed at least partially overlying a corresponding stacked conductive structure to provide one or both of a mechanical package contact for mechanically bonding the resulting IC package to a substrate or other carrier or an electrical package contact for electrically connecting a metal skeleton frame structure formed in the IC package (as described below) to ground or another voltage reference.

Turning to FIG. 5, the method 400 continues at block 410 with a backside grind process in which a backside of the workpiece 425 is subjected to a grinding process or other material removal process to remove a layer of the encapsulant 411 to a depth sufficient to expose the bottom surface of the EGP structure 403, resulting in modified workpiece 427. In implementations in which the microelectronic device(s) 407 are shorter in “height” than the EGP structure 403, additional removal of encapsulant 411 within the inner sidewall of the EGP structure 403 may be performed to expose the backside of the microelectronic device for placement of a thermal paste or thermal interposer.

At block 412, a backside metallization (BSM) process is performed to form a metal layer 429 (one embodiment of the metal layer 160) on the backside surface of the workpiece 427, resulting in modified workpiece 431. The metal layer 429 can include a single metal layer, such as a copper or copper-alloy layer, or can include a buildup of multiple sub-layers, such as a sub-layer of titanium (Ti), followed by a layer of nickel (Ni), followed by a layer of gold (Au) or silver (Ag), or a metal laminate structure, such as laminates of stainless steel and copper (SUS-cu), or any combination thereof. Any of a variety of metallization processes, or combinations thereof, can be employed, such as physical vapor deposition (PVD), sputtering, and the like. Alternatively, the metal layer 429 may be fabricated separately (e.g., as a conductive laminated heat sink structure) and then affixed to the workpiece 427, such as through conductive adhesive, solder reflow, and the like.

Following BSM, at block 414 a singulation process is performed to separate the workpiece 431 from other workpieces in the same panel form via saw or punch singulation to form a resulting IC package 433 (one embodiment of the IC package 102). In some embodiments, the singulation is performed such that the side walls of the resulting IC package 433 extend beyond the EGP structure 403 such that a layer of encapsulant separates the EGP structure 403 from the IC package sidewalls. In other embodiments, the singulation can be performed so that the workpiece 431 is singulated at the exterior sidewall of the EGP structure 403 such that the exterior sidewall of the EGP structure 403 itself forms a portion of the sidewalls of the IC package 433. The IC package 433 then may be subjected to various post-fabrication processes, such as chip sort and packing before the IC package 433 is ultimately mounted on a substrate or other carrier of an electronic device.

Note that not all of the activities or elements described above in the general description are required, that a portion of a specific activity or device may not be required, and that one or more further activities may be performed, or elements included, in addition to those described. Still further, the order in which activities are listed is not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. An integrated circuit (IC) package comprising:
one or more microelectronic devices disposed between a first side and an opposing second side of the IC package; and
a metal frame structure comprising a metal layer disposed at the second side, an embedded ground plane (EGP) structure encircling the one or more microelectronic devices, and a set of stacked conductive structures extending from the EGP structure to the first side through a set of one or more redistribution layers at the first side.

2. The IC package of claim 1, wherein the stacked conductive structures of the set are aligned with a surface of the EGP structure facing the first side.

3. The IC package of claim 2, wherein the set of stacked conductive structures comprises a stacked conductive structure at each corner of the EGP structure.

4. The IC package of claim 1, wherein the stacked conductive structures of the set each comprises a stack of two or more conductive structures, each conductive structure of the stack extending through a corresponding redistribution layer of the set of one or more redistribution layers.

5. The IC package of claim 4, wherein the conductive structure comprises a conductive via.

6. The IC package of claim 1, further comprising:
an array of package contacts disposed at the first side.

7. The IC package of claim 6, wherein the array comprises a package contact overlying, and in electrical contact with, a stacked conductive structure of the set of stacked conductive structures.

8. The IC package of claim 7, wherein the package contact overlying the stacked conductive structure is a mechanical package contact for providing mechanical bonding with another component of an electrical device.

9. The IC package of claim 1, wherein the metal frame structure is composed of at least one of copper or a copper alloy.

10. The IC package of claim 1, wherein the one or more microelectronic devices comprise at least one of one or more surface mount IC devices or one or more IC die.

11. An integrated circuit (IC) package comprising:
an array of package contacts disposed at a first side of the IC package;
a metal layer disposed at an opposing second side of the IC package;
one or more microelectronic devices disposed in the IC package between the first and second sides;
an embedded ground plane (EGP) structure embedded in the IC package between the first and second sides and encircling the one or more microelectronic devices, wherein the EGP structure is mechanically and electrically connected to the metal layer;
a set of redistribution layers disposed between the one or more microelectronic devices and the array of package contacts and comprising conductive structures providing conductive pathways between contacts of the one or more microelectronic devices and corresponding package contacts of the array of package contacts; and
a set of stacked conductive structures disposed at the first side of the IC package and aligned with a surface of the EGP structure facing the first side of the IC package, each stacked conductive structure of the set extending from the first side of the IC package to the surface of the EGP structure through the set of one or more redistribution layers and being mechanically and electrically connected to the surface of the EGP structure.

12. The IC package of claim 11, further comprising:
package encapsulant extending between the metal layer and the set of redistribution layers and encapsulating the one or more microelectronic devices in a volume defined by the EGP structure.

13. The IC package of claim 11, wherein each stacked conductive structure of the set comprises a stack of conductive vias, each conductive via extending through a corresponding redistribution layer of the set of redistribution layers.

14. A method of fabrication of an integrated circuit (IC) package, comprising:
forming a workpiece comprising an embedded ground plane (EGP) structure and one or more microelectronic devices disposed in a volume defined by the EGP structure;
encapsulating the workpiece in an encapsulant;
fabricating a set of redistribution layers at a first side of the workpiece;
fabricating a set of stacked conductive structures that extend from the first side of the workpiece to a first surface of the EGP structure through the set of redistribution layers, each stacked conductive structure being mechanically and electrically connected to the EGP structure at the first surface;
removing encapsulant at a second side of the workpiece opposite the first side to expose a second surface of the EGP structure opposite the first surface; and
forming a metal layer at the second side of the workpiece, the metal layer mechanically and electrically connected to the second surface of the EGP structure.

15. The method of claim 14, wherein each stacked conductive structure includes a stack of conductive structures, and wherein fabricating the set of stacked conductive structures comprises:
for each redistribution layer formed at the first side of the workpiece, forming a corresponding conductive structure for each stack of conductive structures, the conductive structure extending through the redistribution layer.

16. The method of claim 15, wherein forming the corresponding conductive structure comprises forming one of a conductive via that extends through the redistribution layer.

17. The method of claim 14, further comprising:
forming an array of package contacts at the first side of the workpiece after forming the set of redistribution layers.

18. The method of claim 17, wherein forming the array of package contacts further comprises forming a package contact overlying, and in electrical contact with, a stacked conductive structure of the set.

19. The method of claim 14, further comprising:
singulating the workpiece to form the IC package.

20. The method of claim 14, wherein the one or more microelectronic devices comprise at least one of one or more surface mount IC devices or one or more IC die.
